(19) United States
(12) Patent Application Publication
(10) Pub. No.: US 2004/0037438 A1
(43) Pub. Date: Feb. 26, 2004

(54) Method, apparatus, and system for reducing audio signal noise in communication systems

(76) Inventors: Hong You Liu, Guangzhou (CN); Xiao Bang Qian, Shanghai (CN); Kai Young Lu, Guangdong (CN); Simon Lee Guan Huat, Singapore (SG)

Correspondence Address: JOSEPH S. TRIPOLI, THOMSON MULTIMEDIA LICENSING INC., 2 INDEPENDENCE WAY, P. O. BOX 5312, PRINCETON, NJ, 08543-5312, US

(21) Appl. No.: 10/223,839

(22) Filed: Aug. 20, 2002

(51) Int. Cl. H04R 29/00; H03G 3/20; H04B 15/00

(52) U.S. Cl. 381/94.1; 381/56; 381/57

(57) ABSTRACT

A method, apparatus, and system for reducing audio signal noise in a communication system includes, biasing (214)an audio signal noise level beyond a transmission device (200) operating range to condition an audio signal intended to be received by a receiving device (400) having an operating range including the audio signal noise level.

### FIELD OF THE INVENTION

This invention relates to the field of audio communications and, more specifically, to the reduction of noise in an audio signal.

### BACKGROUND OF THE INVENTION

Audio communication systems having transmitting and receiving devices are commonly used in applications such as cordless telephones, cellular telephones, corded telephones, and many other two-way communication devices.

Conventional cordless telephone devices utilize a stationary base unit and a portable handset unit. The base unit is physically and electrically connected to both a source of electrical power and to the telephone company central office. The portable handset unit is wireless and in general communicates with the base unit via a radio frequency link to in turn communicate with an outside party via the telephone company hardwire system. Voice signals from a far party (i.e., an outside party) are received from the hardwire telephone lines by the base unit and transmitted over the RF link to the handset to complete the two-way conversation. Additionally, when a near party (i.e., the party using the handset) speaks into the microphone, a small amount of his own voice is present in the earpiece as a result of a proportion of the speech signal received by a microphone in the portable handset unit being fed back to the output signal produced by the base unit and supplied to the earpiece of the portable handset unit. This is commonly referred to as sidetone. This is a desirable feature in a telephone because it is interactive and gives the user a feeling that the telephone is “alive” and therefore functioning properly. However, the implementation of sidetone in telecommunication systems can introduce noise or static into the output signal produced by the base unit and supplied to the earpiece of the portable handset unit. A major component of this noise in systems implementing sidetone is derived from the audio acoustic noise surrounding the microphone on the portable handset unit. The audio noise is picked up by the microphone on the portable handset unit and transmitted to the base unit. The noise is then amplified by the base unit and transmitted to the far end of the telephone line through the telephone company central office. Meanwhile this noise is transmitted through the audio path (sidetone) to the earpiece of the portable handset unit. The result is a static voice quality signal in the earpiece of the portable handset unit and on the side of the far end talker as well.

### SUMMARY OF THE INVENTION

The invention comprises a method, apparatus, and system for reducing audio signal noise in communication systems.

A method according to one embodiment of the invention for reducing audio signal noise in a communication system includes, determining the level of the audio signal noise, and biasing the audio signal noise level beyond a transmission device operating range to condition the audio signal intended to be received by a receiving device having an operating range including the audio signal noise level.

In another embodiment of the present invention, a transmission device for transmitting audio signals includes a pre-amplifier, for biasing an audio signal noise level of the audio signals beyond a compander operating range, and the compander for compressing the dynamic amplitude range of the audio signals.

In another embodiment of the present invention, a communication system includes at least one pre-amplifier, for biasing an audio signal noise level of audio signals beyond an operating range of at least one transmission device, the at least one transmission device for transmitting the audio signals, the at least one transmission device including a first compander for compressing the dynamic amplitude range of the audio signals, and at least one receiving device for receiving the audio signals from the at least one transmission device, the at least one receiving device including a second compander for expanding the compressed audio signals back to their full dynamic range.

### BRIEF DESCRIPTION OF THE DRAWINGS

The teachings of the present invention can be readily understood by considering the following detailed description in conjunction with the accompanying drawings, in which:

FIG. 1 depicts a block diagram of an embodiment of a cordless telephone system;

FIG. 2 depicts an embodiment of a transmitting circuit, suitable for use in the portable handset unit of the cordless telephone system of FIG. 1;

FIG. 3 graphically depicts a response curve of a typical 2:1 compressor suitable for use in the transmitting circuit of the portable handset unit of the cordless telephone system of FIG. 1;

FIG. 4 depicts an embodiment of a receiving circuit suitable for use in the base unit of the cordless telephone system of FIG. 1;

FIG. 5 graphically depicts a response curve of a typical 1:2 expander suitable for use in the receiving circuit of the base unit of the cordless telephone system of FIG. 1; and

FIG. 6 graphically depicts a response curve of a typical 2:1 compressor suitable for use in the transmitting circuit of the portable handset unit of the cordless telephone system of FIG. 1, operating on an audio signal conditioned in accordance with the present invention.

To facilitate understanding, identical reference numerals have been used, where possible, to designate identical elements that are common to the figures.

### DETAILED DESCRIPTION OF THE INVENTION

The present invention will be described within the context of a cordless telephone system and associated devices. However, it will be appreciated by those skilled in the art that the subject invention may be advantageously employed in any system having transmitting and receiving devices wherein a compander is implemented. Thus, it is contemplated by the inventors, that the subject invention has broad applicability beyond the cordless telephone system described herein. The invention may be used to provide a means for reducing noise in an audio signal transmitted from a transmission device and supplied to a receiving device.

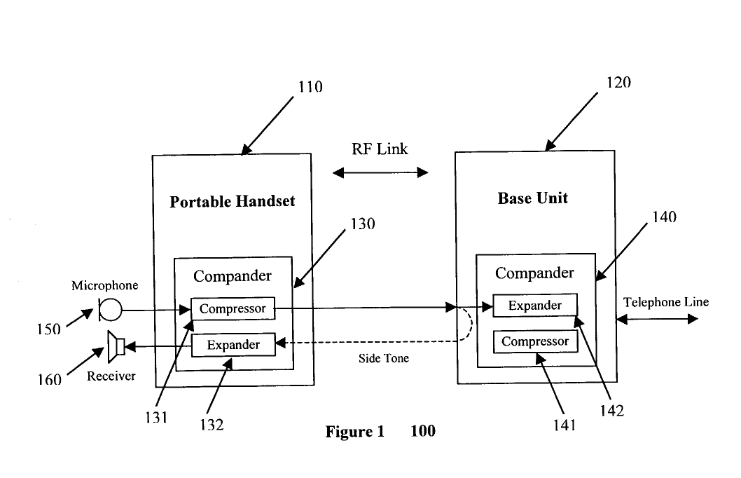

FIG. 1 depicts a block diagram of an embodiment of a cordless telephone system 100. The cordless telephone system 100 includes a base unit 120 and a portable handset unit 110. The base unit 120 is physically and electrically connected to both a source of electrical power and to a telephone company hardwire system. The portable handset unit 110 is wireless and in general communicates with the base unit 120 via a radio frequency link to in turn communicate with a caller connected to the other end of the telephone company hardwire system (herein referred to as a far end talker). Voice signals from the far end talker are received from the hard-wire telephone lines by the base unit 120 and transmitted over the RF link to the portable handset unit 110. Voice signals from the microphone 150 of the portable handset unit 110 are transmitted to the base unit 120. A portion of the voice signals from the microphone 150 of the portable handset unit 110 is routed, by the base unit 120, to the hard-wire telephone line. The other portion of the voice signal is sent back to the earpiece 160 of the portable handset unit 110 through a sidetone circuit. This completes the two-way conversation. The portable handset unit 110 of the cordless telephone system 100 includes a compander 130. The compander 130 of the portable handset unit 110 includes a compressor 131 and an expander 132 as a part of a transmitting circuit. The base unit 120 of the cordless telephone system 100 also includes a compander 140. The compander of the base unit 120 includes a compressor 141 and an expander 142 as a part of a receiving circuit.

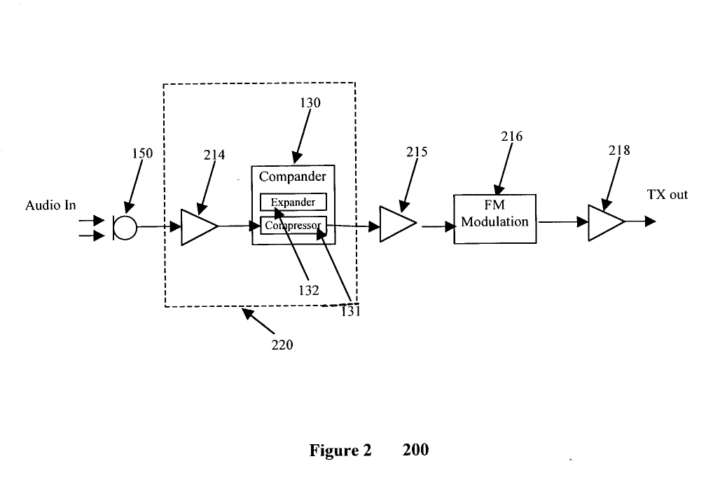

FIG. 2 depicts an embodiment of a transmitting circuit 200, suitable for use in the portable handset unit 110 of the cordless telephone system 100 of FIG. 1. The transmitting circuit 200 of the portable handset unit 110 includes a microphone 150, an amplifier 214, a compander 130 including a compressor 131 and an expander 132, an audio amplifier 215, a modulation block 216 (illustratively a frequency inversion scrambler), and an output audio amplifier 218.

An audio signal originates in the microphone 150 in the transmitting circuit 200 of the portable handset unit 110. The audio signal then propagates through the compressor 131 of the transmitting circuit 200. The microphone amplifier 214 adjusts the level of audio signal to be processed by the compressor 131. The compressor 131 compresses the dynamic amplitude range of the audio signal from the microphone 150 in preparation for transmission across a narrow-band transmission link. The signal then propagates through the audio amplifier 215 to adjust the audio signal to a standard level. Subsequently, the signal is processed through a frequency inversion scrambler 216 that inverts the frequency spectrum. Frequency inversion is optional but useful in cordless telephone systems to add privacy of transmitted signals. The inverted frequency spectrum is buffered through an amplifier 218 for providing the output signal TX OUT. The output signal TX OUT is FM modulated and transmitted by radio link to a receiving circuit in the base unit 120 of the cordless telephone system 100 of FIG. 1.

In cordless telephone systems, the audio signal from a microphone on a portable handset unit includes not only the voice of the party speaking into the microphone (herein referred to as a near end talker), but also any ambient sound picked up by a microphone within the dynamic range of a compander of a transmitting circuit in a portable handset unit. This extraneous ambient sound noise is referred to as audio signal noise. If audio signal noise is transmitted by a transmitting circuit of a portable handset unit to a receiving circuit in a base unit of a cordless telephone system, the result is a degradation in the quality of an audio signal not only in an earpiece of a portable handset unit through a sidetone circuit of the base unit, but also in the far end telephone line.

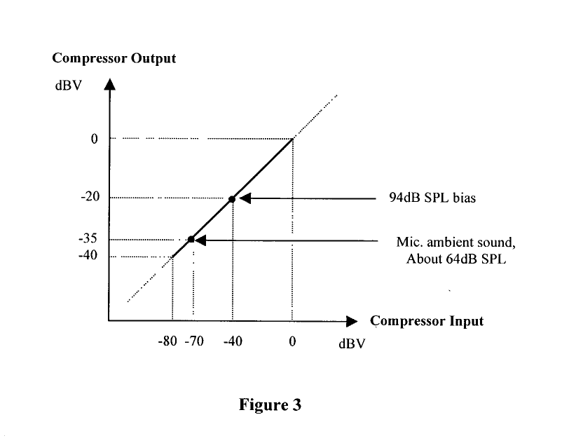

FIG. 3 graphically depicts a response curve of a typical 2:1 compressor suitable for use in the transmitting circuit 200 of the portable handset unit 110 of the cordless telephone system 100 of FIG. 1. FIG. 3 illustrates how audio signal noise in an audio signal is compressed by the compressor 131 of the compander 130 of the transmitting circuit 200 of the portable handset unit 110. The dynamic range of the compressor 131 in FIG. 3 is −80 dBV to 0 dBV. The normal sound level of an audio signal received by the microphone 150 of the portable handset unit 110 is typically 94 dB SPL (approximately −40 dBV). Additionally, the inventors have determined that the audio signal noise component of an audio signal of a microphone of a portable handset unit as in the cordless telephone system 100 of FIG. 1, is 64 dB SPL (approximately −70 dBV). It will be appreciated by those skilled in the art that the audio signal noise level of cordless telephone systems can be readily measured by the microphone of a portable handset unit or by any other means known to those skilled in the art. Thus, it is evident that both the normal sound level (−40 dBv) and the audio signal noise level (−70 dBv) are included within the dynamic range of the compressor 131 in the portable handset unit 110. As such, the −40 dbV normal sound signal and the −70 dBV audio signal noise signal are compressed to −20 dBV and −35 DBV, respectively, and are transmitted to an expander in a receiving circuit of the base unit 120 through RF link.

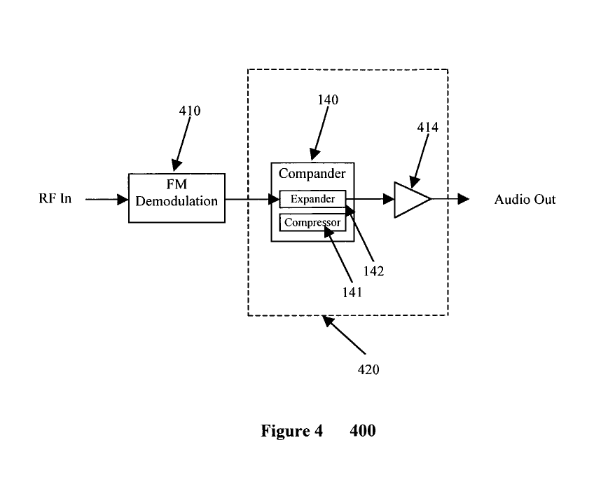

FIG. 4 depicts an embodiment of a receiving circuit 400, suitable for use in the base unit 120 of the cordless telephone system 100 of FIG. 1. The compressed and FM modulated signal from the transmitting circuit 200 of the portable handset unit 110 is applied as RF In to the receiving circuit 400 of the base unit 120. The receiving circuit 400 of the base unit 120 includes a demodulation block 410 (illustratively an FM demodulator), a compander 140 including a compressor 141 and an expander 142, and an output audio amplifier 414.

The receiving circuit 400 in the base unit 120 receives the compressed and FM modulated signal from the transmitting circuit 200 of the portable handset unit 110 and propagates the signal through the demodulation block 410. As discussed above, the audio signal from the microphone 150 of the portable handset unit 120 includes not only the voice of the near end talker, but also the audio signal noise picked up by the microphone 150 and compressed by the compressor 131 of the transmitting circuit 200. Through the FM demodulator 410, the signal is re-inverted back to its original frequency spectrum. The FM demodulator 410 is optional but useful in cordless telephones where, in combination with the frequency inversion scrambler 216 of the transmitting circuit 200 of the portable handset unit 110 provides privacy of the conversation between conversing parties. The output signal of the FM demodulator 410 is applied to the expander 142 of the receiving circuit 400 of the base unit 120. The expander 142 decompresses the narrow-band compressed signal RF In of the transmitting circuit 200 of the portable handset unit 110 to return it to its full dynamic range for a far end talker to hear the received voice signal. The output signal of the expander 142 is then amplified by the output amplifier 414 to provide the voice signal from the near end talker to the far end talker. The signal is subsequently transmitted over conventional telephone lines to the far end talker.

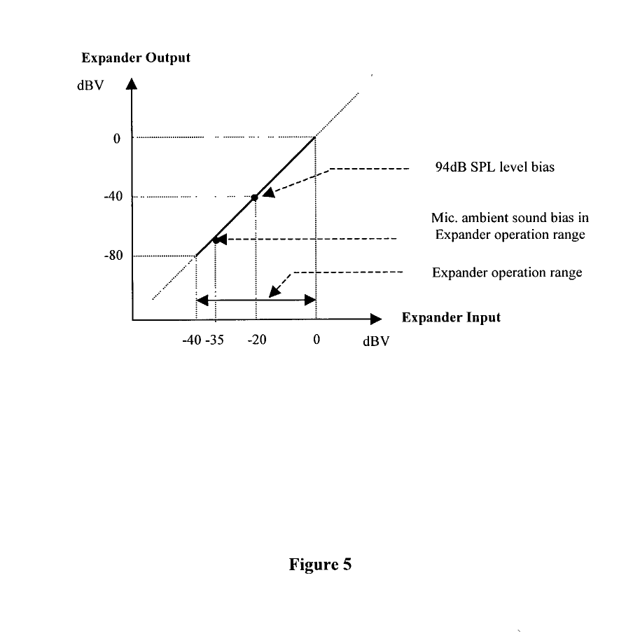

FIG. 5 graphically depicts a response curve of a typical 1:2 expander suitable for use in the receiving circuit 400 of the base unit 120 of the cordless telephone system 100 of FIG. 1. FIG. 5 illustrates how the compressed signals transmitted from the portable handset unit 110 are expanded at the proportion of 1:2. As depicted, the input dynamic range of the 1:2 expander 142 of FIG. 4 is −40 dB to 0 dB. As such, normally the compressed −20 dBV normal sound signal and the compressed −35 dBV audio signal noise discussed above, are transmitted into the expander 142 of the base unit 120 through RF link from the portable handset unit 110 and expanded back to −40 dBV and −70 dBV by the expander 142 in the base unit 120. This results in a degradation of the quality of an audio signal not only in the earpiece 160 of the portable handset unit 110 through a sidetone circuit of the base unit 110, but also in the far end telephone line.

In accordance with the present invention, the audio signal from the microphone 150 of the portable handset unit 110 is biased by an amplifier such that the dynamic range of the compressor 131 does not include the level of audio signal noise picked up by the microphone 150 and as such is not compressed by the compressor 131 in the transmitting circuit 200 of the portable handset unit 110 and is not transmitted to a receiving circuit of the base unit 120. Briefly stated, the gain of the amplifier 214 of the transmitting circuit 200 of the portable handset unit 110 is adapted to attenuate by 20 dB; that is −40 dBV normal sound signal and −70 dBV audio signal noise become −60 dBV and −90 dBV respectively, while maintaining the dynamic range of the compressor 131 at −80 dBV to 0 dBV. Thus the −90 dBV audio signal noise is out of the operating range of the compressor 131 of the transmitting circuit 200 of the portable handset unit 110.

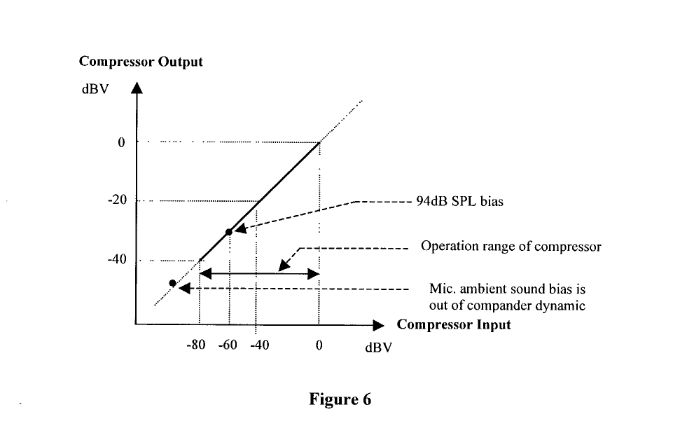

FIG. 6 graphically depicts a response curve of a typical 2:1 compressor suitable for use in the transmitting circuit 200 of the portable handset unit 110 of the cordless telephone system 100 of FIG. 1, operating on an audio signal conditioned in accordance with the present invention. The gain of the amplifier 214 of the transmitting circuit 200 of the portable handset unit 110 is adapted to produce attenuations in the normal sound signal and the audio signal noise of −20 dBv. The normal sound signal and audio signal noise become −60 dBV and −90 dBV, respectively. Since the dynamic range of the compressor 131 is still −80 dBV to 0 dBV, the compressor 131 would not work effectively at the level of the audio signal noise, −90 dBv. That is, the audio signal noise would not be compressed at the proportion of 2:1, it would be between 2:1 and 1:1, depending on the specification and performance of the compressor 131. As such, the output of the compressor 131 for the normal sound signal and the audio signal noise are −30 dBV and −50 dBV, respectively.

After compressing, the normal sound signal, −30 dBv, and the audio signal noise, −50 dBv, are compensated +10 dB by the audio amplifier 215 of the transmitting circuit 200 of the portable handset unit 110 for standard modulation. As such, the −30 dbV normal sound signal and the −50 dBV audio signal noise are compensated to −20 dBV and −40 DBV, respectively. The compressed and compensated signals are then modulated by the modulation block 216, and transmitted to an expander in the base unit 120 through RF link. As mentioned above and with reference to FIG. 4, the input dynamic range of a typical expander in a receiving circuit of the base unit 120 has an input dynamic range of −40 dBV to 0 dBV and 1:2 proportion. As such, the signal comprising a range of −20 dBV to −40 dBV transmitted from the transmitting circuit 200 of the portable handset unit 110 is expanded to −40 dBV and −80 dBV. Comparing to the −40 dBV signal and −70 dBV audio signal noise discussed above with reference to FIG. 3, there is a 10 dB audio signal noise attenuation in the signal transmitted to the base unit 120. The attenuation of the audio signal noise results in better audio signal quality in the receiver of the far end of the telephone line.

By the same principle, the expander 132 in the portable handset unit will also experience the same 10 dB audio signal noise attenuation in the signal transmitted from transmitting circuit 200 of the portable handset unit, resulting in better audio quality in the earpiece 160 of the portable handset unit 110 via the sidetone circuit of the base unit 120. Additionally, by biasing the compressor 141 of the base unit 120 in a substantially similar manner as described above for the compressor 131 of the portable handset unit 1 10, better audio quality in the earpiece 160 of the portable handset unit 110 can be achieved.

It will be appreciated by those skilled in the art that a cordless telephone system or the like can be advantageously adapted to configure the compressor of either a portable handset unit or a base unit, or both, or in any combination, and still be within the bounds of the present invention.

While the forgoing is directed to some embodiments of the present invention, other and further embodiments of the invention may be devised without departing from the basic scope thereof. As such, the appropriate scope of the invention is to be determined according to the claims, which follow.

What is claimed is:

1. A method for reducing audio signal noise in a communication system, comprising:
determining (150) a level of said audio signal noise; and
biasing (214) said audio signal noise level beyond a transmission device (200) operating range to condition an audio signal intended to be received by a receiving device (400) having an operating range including said audio signal noise level.

2. The method of claim 1, wherein said audio signal noise originates in said transmission device (200).

3. The method of claim 1, wherein said communication system is a cordless telephone system (100).

4. The method of claim 3, wherein said transmission device (200) is a handset unit (110).

5. The method of claim 4, wherein said audio signal noise originates in a microphone (150).

6. The method of claim 5, wherein said microphone (150) is used to determine said level of said audio signal noise.

7. The method of claim 3, wherein said receiving device (400) a base unit (120).

8. The method of claim 1, wherein said operating range comprises a dynamic amplitude range, said biasing (214) causing an amplitude range of said audio signal noise to be beyond said operating range.

9. The method of claim 1, wherein said audio signal noise is biased using a pre-amplifier (214).

10. A transmission device for transmitting audio signals, comprising:
a pre-amplifier (214), for biasing an audio signal noise level of said audio signals beyond a compander (130) operating range; and
said compander (130) for compressing the dynamic amplitude range of said audio signals.

11. The transmission device of claim 10, wherein said compander (130) comprises a compressor (131).

12. A communication system, comprising:
at least one pre-amplifier (214), for biasing an audio signal noise level of audio signals beyond an operating range of at least one transmission device (200);
said at least one transmission device (200) for transmitting said audio signals, said at least one transmission device (200) comprising a first compander (130) for compressing the dynamic amplitude range of said audio signals; and
at least one receiving device (400) for receiving said audio signals from said at least one transmission device (200), said at least one receiving device (400) comprising a second compander (140) for expanding the compressed audio signals back to their full dynamic range.

13. The communication system of claim 12, wherein said at least one receiving device (400) transmits a portion of said audio signals back to said at least one transmission device (200).

14. The communication system of claim 13, wherein the portion of said audio signals transmitted back to said at least one transmission device (200) is used to create a sidetone for said at least one transmission device (200).

15. The communication system of claim 12, wherein said audio signals originate in said at least one transmission device (200).

16. The communication system of claim 12, wherein said communication system is a cordless telephone system (100).

17. The communication system of claim 16, wherein said at least one transmission device (200) is a handset unit (110).

18. The communication system of claim 16, wherein said at least one receiving device (400) is a base unit (120).

19. The communication system of claim 12, wherein said first compander (130) comprises a compressor (131).

20. The communication system of claim 12, wherein said second compander (140) comprises an expander (142).
